(19) United States
(12) Patent Application Publication
(10) Pub. No.: US 2008/0194065 A1
(43) Pub. Date: Aug. 14, 2008

(54) INTEGRATED CIRCUIT DEVICES HAVING AN EPITAXIAL PATTERN WITH A VOID REGION FORMED THEREIN AND METHODS OF FORMING THE SAME

(75) Inventors: Sung-Young Lee, Gyeonggi-do (KR); Sung-Min Kim, Inchen-si (KR); Dong-Gun Park, Gyeonggi-do (KR); Kyoung-Hwan Yeo, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/107,468

(22) Filed: Apr. 22, 2008

Related U.S. Application Data
(62) Division of application No. 10/835,760, filed on Apr. 30, 2004.

(30) Foreign Application Priority Data
May 2, 2003 (KR) 2003-28287

(51) Int. Cl. H01L 21/02

(52) U.S. Cl. 438/151

(57) ABSTRACT

An integrated circuit device includes a substrate. An epitaxial pattern is on the substrate and has a pair of impurity diffusion regions formed therein and a pair of void regions formed therein that are disposed between the pair of impurity diffusion regions and the substrate. Respective ones of the pair of impurity diffusion regions at least partially overlap respective ones of the pair of void regions. A gate electrode is on the epitaxial pattern between respective ones of the pair of impurity diffusion regions.

### RELATED APPLICATION

This application claims priority to and the benefit of Korean Patent Application No. 2003-28287, filed May 2, 2003 and U.S. patent application Ser. No. 10/835,760, filed on Apr. 30, 2004, the disclosures of which are hereby incorporated herein by reference.

### FIELD OF THE INVENTION

The present invention relates to integrated circuit devices and methods of forming the same, and, more particularly, integrated circuit transistor devices and methods of forming the same.

### BACKGROUND OF THE INVENTION

As semiconductor devices become more highly integrated to enhance performance, speed, and/or cost effectiveness, various problems may arise. Examples of such problems include a short channel effect, such as punch-through, an increase in parasitic capacitance (e.g., a junction capacitor) between a junction region and a substrate, and an increase in a leakage current etc.

To address these problems, a double-gate-field-effect transistor technique has been introduced. In the double-gate-field-effect (FET) technique, gate electrodes are formed on both sides of a channel. As a result, short channel effects may be reduced. However, problems with parasitic capacitance and leakage current may persist.

To alleviate these problems, a field-effect transistor technique using silicon-on-insulator (SOI) technology where an insulating layer is disposed on a silicon substrate has been suggested. Unlike conventional techniques where a field effect transistor is formed on bulk silicon and an active region is formed in the bulk silicon, a SOI FET has an active region formed in a silicon on insulator layer.

The SOI FET technique may have certain advantages, such as low operation voltage, effective device isolation, control of junction leakage current, and reduction of short channel effects. The SOI FET technique may have the problem of a floating body effect, which is caused by accumulation of heat and electron-hole pairs in the silicon on insulator during device operation. Due to the floating body effect, the SOI FET technique may result in variations in threshold voltage and may not provide sufficient device reliability. The SOI FET technique may also generate stresses in an integrated circuit device, which result from different thermal expansion coefficients between a substrate and an insulating layer. In addition, the fabrication cost of an SOI substrate may be expensive.

### SUMMARY

According to some embodiments of the present invention, an integrated circuit device comprises a substrate. An epitaxial pattern is on the substrate and has a pair of impurity diffusion regions formed therein and a pair of void regions formed therein that are disposed between the pair of impurity diffusion regions and the substrate. Respective ones of the pair of impurity diffusion regions at least partially overlap respective ones of the pair of void regions. A gate electrode is on the epitaxial pattern between respective ones of the pair of impurity diffusion regions.

In other embodiments of the present invention, the epitaxial pattern is directly on the substrate.

In still other embodiments of the present invention, respective oxide layers are disposed in respective ones of the pair of void regions. In addition, respective nitride layers may be disposed on respective ones of the pair of oxide layers.

In further embodiments of the present invention, the epitaxial pattern comprises silicon and/or silicon-germanium.

In still further embodiments of the present invention, the gate electrode comprises polysilicon and/or metal silicide.

In still further embodiments of the present invention, the void regions are filled with an insulating material.

In still further embodiments of the present invention, a device isolation layer is disposed adjacent to the epitaxial pattern and has an upper surface, opposite the substrate, that is lower than an upper surface of the epitaxial pattern, opposite the substrate.

In other embodiments of the present invention, an integrated circuit device comprises a substrate. An epitaxial pattern is on the substrate and has a pair of impurity diffusion regions formed therein and a void region formed therein that is between respective ones of the pair of impurity diffusion regions. A gate electrode is on the epitaxial pattern between respective ones of the pair of impurity diffusion regions. The gate electrode at least partially overlaps the void region.

Although described above with respect to device embodiments of the present invention, it will be understood that the present invention may also be embodied as methods of forming an integrated circuit device.

### BRIEF DESCRIPTION OF THE DRAWINGS

Other features of the present invention will be more readily understood from the following detailed description of specific embodiments thereof when read in conjunction with the accompanying drawings, in which:

FIG. 1A is a perspective view of an integrated circuit device in accordance with some embodiments of the present invention;

FIG. 1B is a cross sectional view of the integrated circuit device of FIG. 1A in accordance with some embodiments of the present invention;

FIG. 2A is a perspective view of an integrated circuit device in accordance with further embodiments of the present invention;

FIG. 2B is a cross sectional view of the integrated circuit device of FIG. 2A in accordance with further embodiments of the present invention;

FIGS. 3A-10A are perspective views that illustrate methods of forming the integrated circuit device of FIGS. 1A and 1B in accordance with some embodiments of the present invention;

FIGS. 3B-10B are cross sectional views that illustrate methods of forming the integrated circuit device of FIGS. 1A and 1B in accordance with some embodiments of the present invention;

FIGS. 11A-17A are perspective views that illustrate methods of forming the integrated circuit device of FIGS. 2A and 2B in accordance with further embodiments of the present invention; and

FIGS. 11B-17B are cross sectional views that illustrate methods of forming the integrated circuit device of FIGS. 2A and 2B in accordance with further embodiments of the present invention.

### DETAILED DESCRIPTION OF EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like numbers refer to like elements throughout the description of the figures. In the figures, the dimensions of layers and regions are exaggerated for clarity. It will also be understood that when an element, such as a layer, region, or substrate, is referred to as being “on” another element, it can be directly on the other element or intervening elements may be present. In contrast, when an element, such as a layer, region, or substrate, is referred to as being “directly on” another element, there are no intervening elements present.

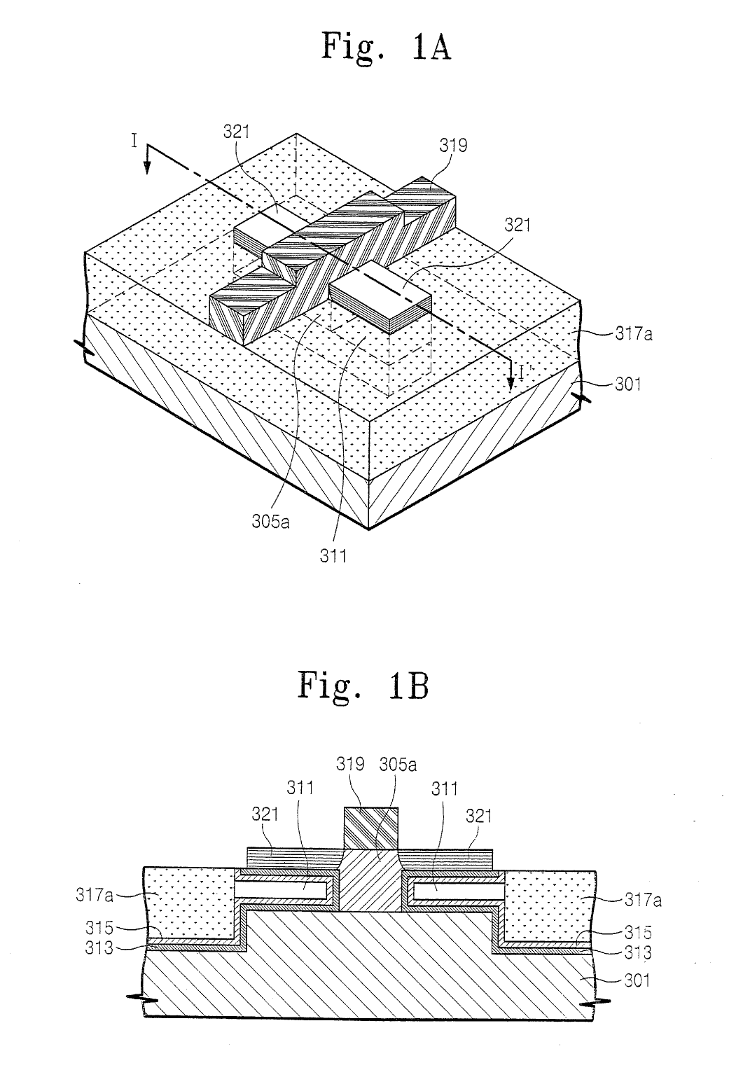

Referring now to FIGS. 1A and 1B, an integrated circuit device according to some embodiments of the present invention comprises a substrate 301 that contains a silicon element. A device isolation region 317a is formed on the substrate 301. The device isolation region 317a may be an oxide layer. An epitaxial pattern 305a is in contact with the substrate 301. The epitaxial pattern 305a may comprise silicon or silicon-germanium, for example. The device isolation region 317a defines the epitaxial pattern 305a. That is, neighboring epitaxial patterns 305a are electrically isolated from each other by the device isolation region 317a. A gate electrode 319 is formed on the epitaxial pattern 305a and the device isolation region 317a. Impurity diffusion regions 321, which are implanted with ions, are formed in the epitaxial pattern 305a outside of the gate electrode 319. An empty space or void region 311 is disposed under the impurity diffusion regions 321. The empty space or void region 311 is used as an insulating region. The gate electrode 319 may comprise silicon, a multi-layered electrode, or a metal electrode, for example. The multi-layered electrode or the metal electrode may comprise polysilicon and/or a metal silicide, which are stacked sequentially.

According to the present embodiment, the epitaxial pattern 305a between the impurity diffusion regions 321 is directly in contact with the substrate 301. In addition, an empty space or void region 311 is disposed between the impurity diffusion regions 321 and the substrate 301. As a result, short channel and floating body effects can be reduced. Furthermore, a junction capacitance may not be generated between the impurity diffusion regions 321 and the substrate 301.

According to some embodiments of the present invention, a thermal oxide layer 313 and a liner nitride layer 315 may be formed as shown in FIG. 1B so as to fill a portion of the empty space or void region 311 and to be disposed between the device isolation region 317a and the substrate 301. In other embodiments, the empty space region 311 may be filled with an insulating layer, such as, for example, the device isolation layer 317a.

In some embodiments of the present invention, the device isolation region 317a has a top surface lower than a top surface of the epitaxial pattern 305a. The gate electrode 319 controls the channel through the top and/or side of the epitaxial pattern 305a. As a result, short channel effects may be reduced and the effective channel region may be increased.

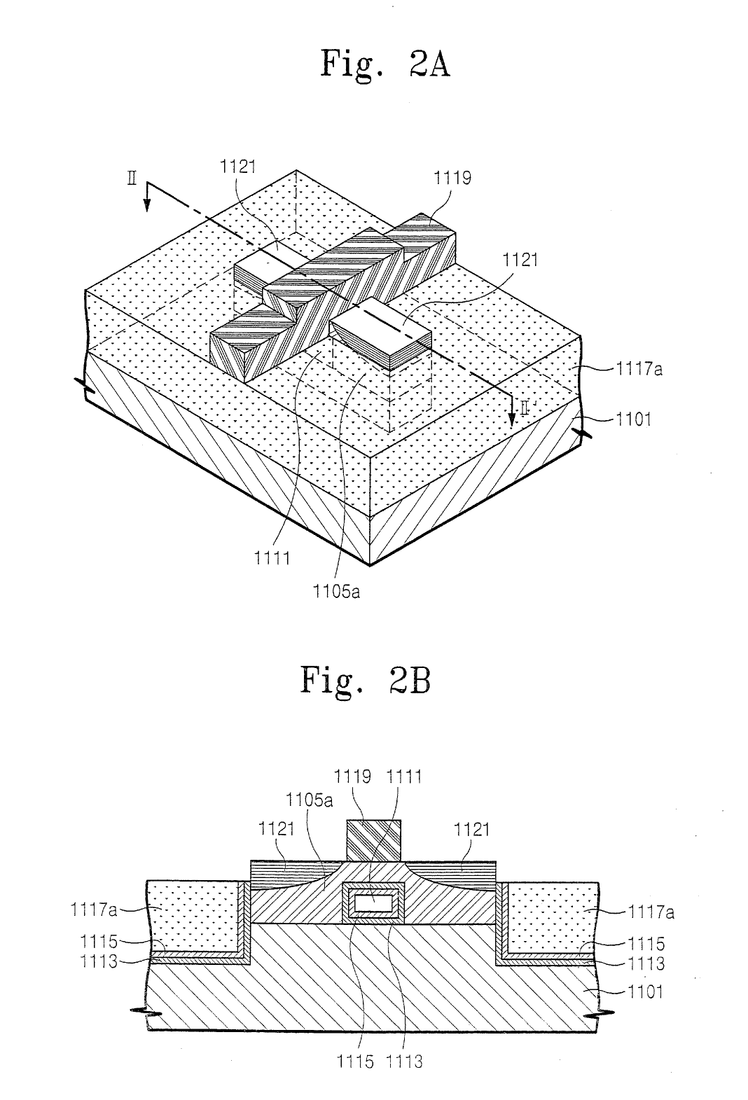

FIG. 2A and FIG. 2B are perspective/cross-sectional views of an integrated circuit device in accordance with further embodiments of the present invention, respectively. FIG. 2B is a cross-sectional view taken along line II-II′ of FIG. 2A. Different from the embodiments described above with respect to FIGS. 1A and 1B, an empty space or void region 1111 or an insulating region is disposed in an epitaxial pattern 1105a under a gate electrode 1119 between impurity diffusion regions 1121. The epitaxial pattern 1105a under the impurity diffusion regions 1121 is in contact with the substrate 1101.

Referring to FIGS. 2A and 2B, the integrated circuit device, according to some embodiments of the present invention, comprises a substrate 1101 with a device isolation region 1117a and the epitaxial pattern 1105a formed thereon. Both ends of the epitaxial pattern 1105a are in contact with the substrate 1101. The gate electrode 1119 is formed on the epitaxial pattern 1105a and on the device isolation region 1117a. Impurity diffusion regions 1121 implanted with impurity ions are formed in the epitaxial pattern 1105a outside of the gate electrode 1119. The empty space or void region 1111 is formed in the epitaxial pattern 1105a under the gate electrode 1119 between the impurity diffusion regions 1121.

According to some embodiments of the present embodiment, because the empty space or void region 1111 is formed under the channel region in the epitaxial pattern 1105a and between the impurity diffusion regions 1121, short channel effects may be reduced. In addition, because the epitaxial pattern 1105a under the impurity diffusion regions 1121 is in contact with the substrate 1101, floating body effects may also be reduced.

As shown in FIG. 2B, a thermal oxide layer 1113 and a liner nitride layer 1115 may be formed so as to fill a potion of the empty space region 1111. In the same way, the thermal oxide layer 1113 and the liner nitride layer 1115 may be formed between the device isolation layer 1117a and the substrate 1101. In some embodiments, the empty space or void region 1111 may be filled with an insulating layer. For example, the device isolation layer 1117a may be extended to fill the empty space or void region 1111.

In some embodiments of the present invention, the device isolation region 1117a has a top surface lower than a top surface of the epitaxial pattern 1105a, The gate electrode 319 controls the channel through the top and/or side of the epitaxial pattern 305a. As a result, short channel effects may be reduced and the effective channel region may be increased.

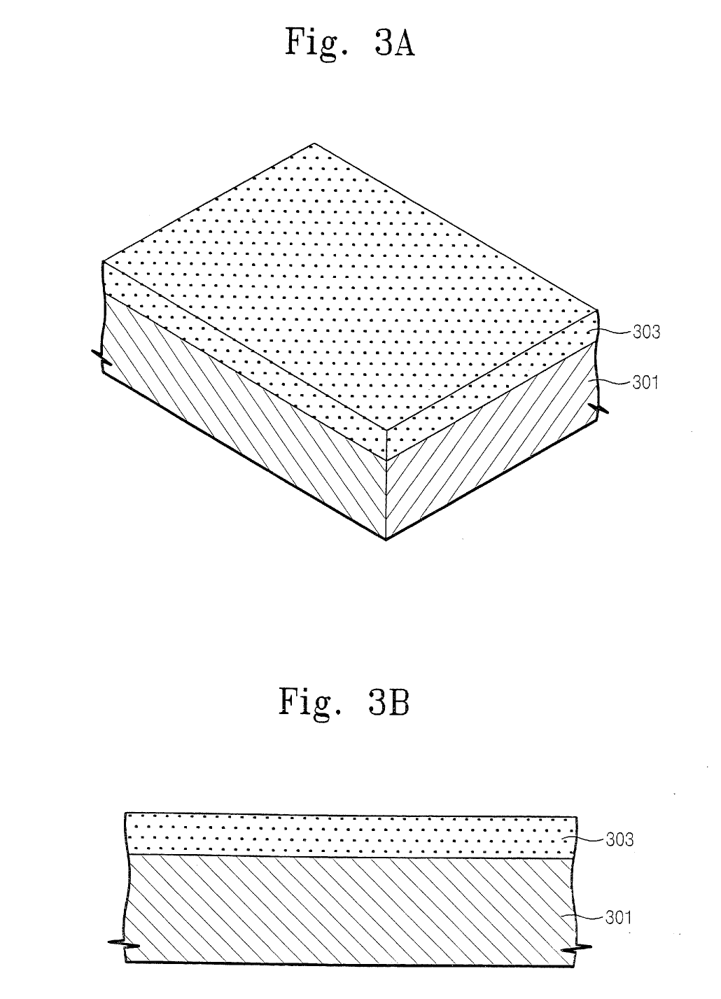

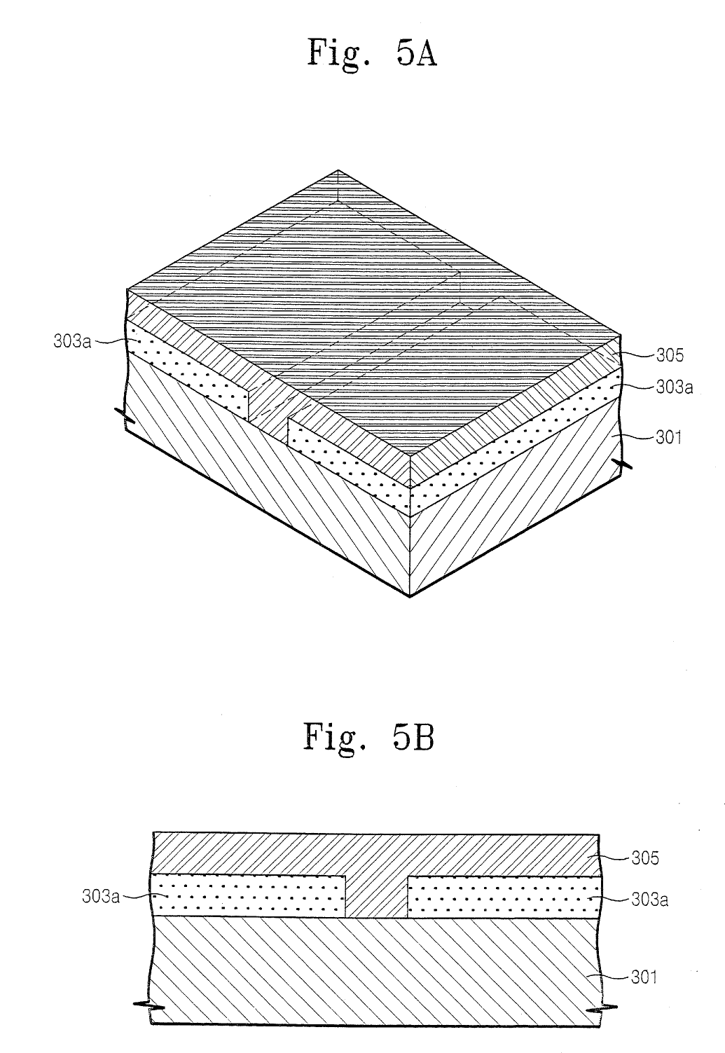

Referring now to FIG. 3A through FIG. 10A and FIG. 3B through FIG. 10B, methods of fabricating integrated circuit devices illustrated, for example, in FIG. 1A and FIG. 1B are described. As shown in FIGS. 3A and 3B, an epitaxial sacrificial layer 303 is formed on a substrate 301. The substrate 301 may be a semiconductor substrate comprising silicon. The epitaxial sacrificial layer 303 may comprise a material having a crystalline structure on which a subsequent epitaxial layer (305 of FIGS. 5A and 5B) may be grown. In other words, if the epitaxial layer comprises silicon, then the epitaxial sacrificial layer 303 may comprise single crystalline silicon. That is, the epitaxial sacrificial layer 303 may comprise a material having the same or similar crystalline structure as silicon and a lattice constant similar to silicon. For example, the epitaxial sacrificial layer 303 may comprise Si—Ge, CeO₂ and/or CaF₂. These materials are merely examples of suitable materials for the epitaxial sacrificial layer. Any material having an etch selectivity with respect to the epitaxial layer (described later) and having a crystalline structure that facilitates the growth of the epitaxial layer can be used.

For example, a silicon-germanium epitaxial sacrificial layer may be formed using source gases, such a di-chloro-silane (DCS), GeH₄, HCl and H₂ and the like. Depending on the thickness of the epitaxial sacrificial layer 303, the thickness of an empty space or void region or an insulating region may be determined. Accordingly, the empty space or void region or the insulating region may be formed to suit various device characteristics by controlling the thickness of the epitaxial sacrificial layer 303.

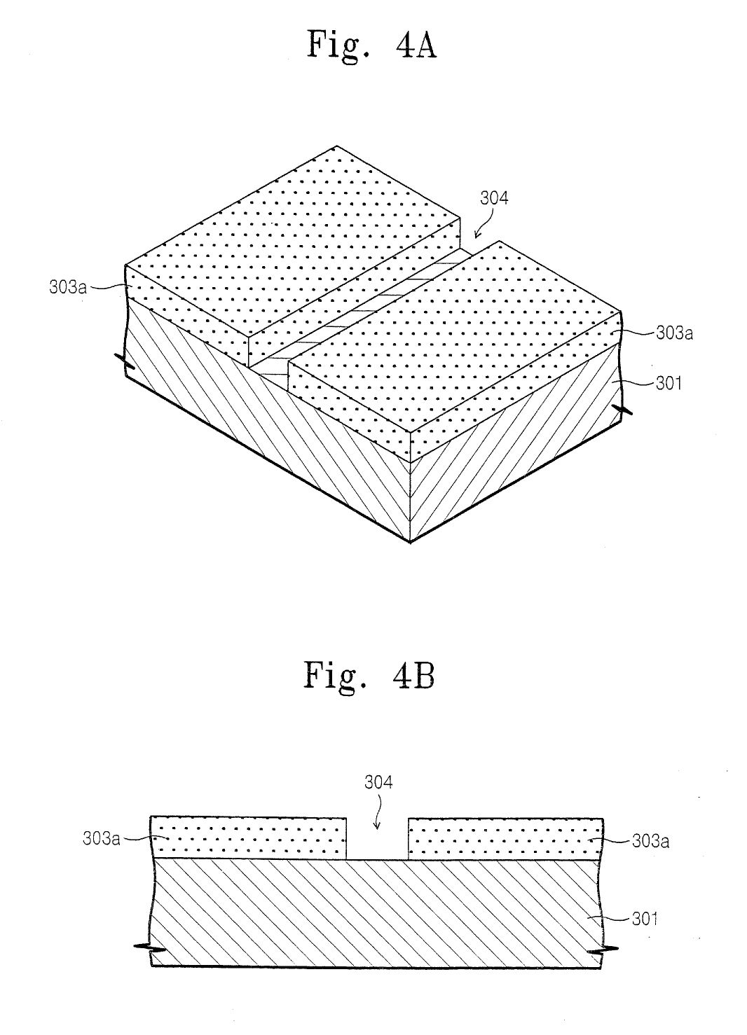

Referring to FIG. 4A and FIG. 4B, the epitaxial sacrificial layer 303 is patterned to form an epitaxial sacrificial pattern 303a exposing a predetermined region of the substrate 301. That is, a groove 304 is defined by the epitaxial sacrificial pattern 303a that exposes a predetermined region of the substrate 301.

Referring to FIG. 5A and FIG. 5B, an epitaxial layer 305 having a planarized top is formed on the exposed substrate 301 and the epitaxial sacrificial pattern 303a. The epitaxial layer 305 may be formed by growing the epitaxial layer to have a planar top surface. If the top of the epitaxial layer 305 is not planarized based on epitaxial growth, the top of the epitaxial layer 305 can be planarized using a planarizing process. The planarization process may be unnecessary if the top of the epitaxial layer 305 is sufficiently planar from the growth process.

For example, the epitaxial layer 305 may comprise a silicon layer, which fills the groove 304 and is in contact with the substrate 301 as shown in FIG. 5B. In addition, the epitaxial layer 305 is formed on the epitaxial sacrificial pattern 303a. If the epitaxial sacrificial layer 303 comprises Si—Ge, CeO₂, CaF₂ or the like, then it may be advantageous to form the epitaxial layer 305 using silicon. If the epitaxial sacrificial layer 303 comprises silicon, then it may be advantageous to form the epitaxial layer 305 using Si—Ge.

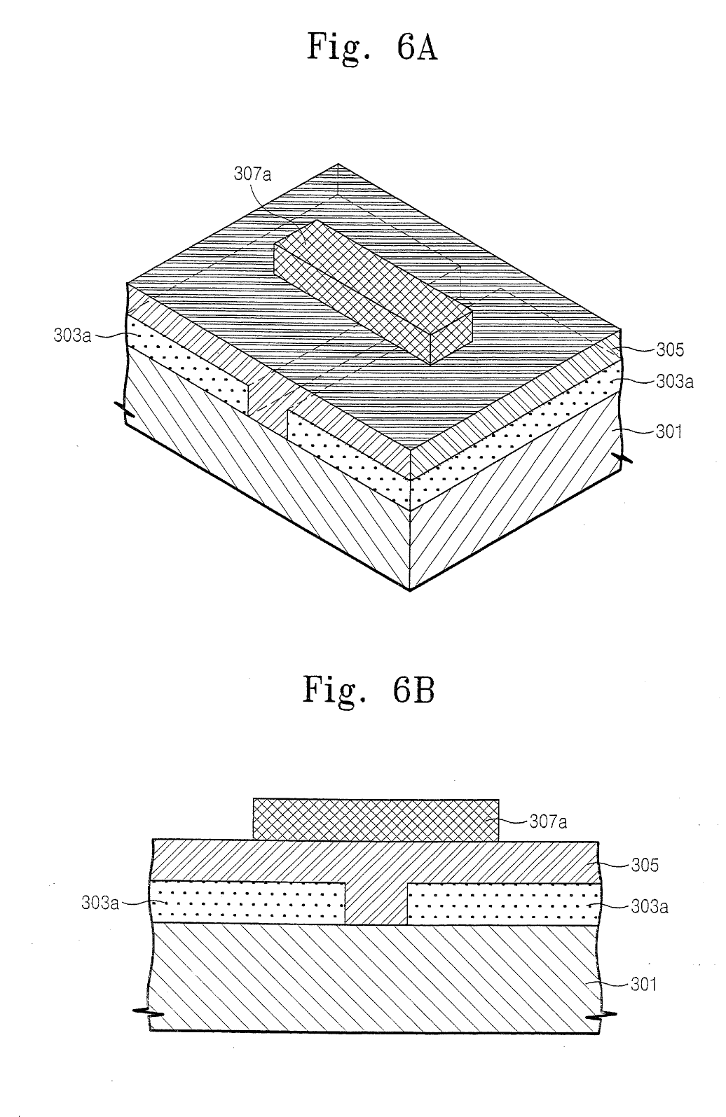

Referring now to FIG. 6A and FIG. 6B, a mask pattern 307a is formed on the epitaxial layer 305. The portion of the epitaxial layer 305 covered by the mask pattern 307a serves as an active region. The mask pattern 307a is formed to cross the groove 304.

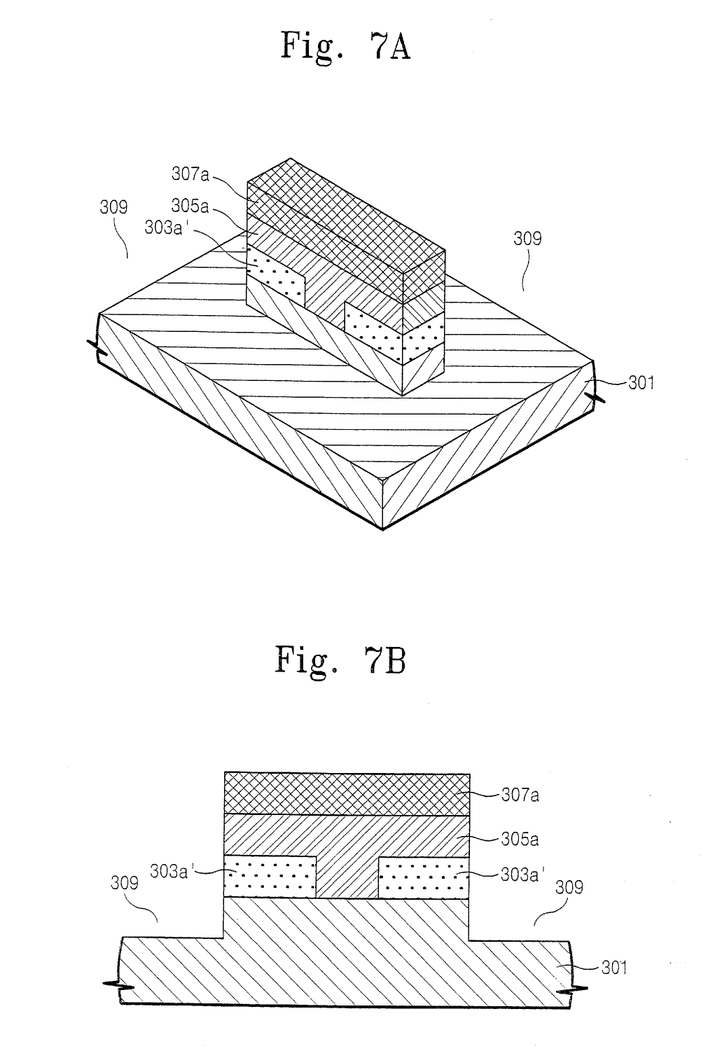

Referring now to FIG. 7A and FIG. 7B, an anisotropic etching process is performed using the mask pattern 307a as an etching mask until the substrate 301 is partially etched. The epitaxial layer 305 exposed by the mask pattern 307a, the epitaxial sacrificial pattern 303a, and a portion of the substrate 301 are removed to form a trench 309 in the substrate 301 for device isolation. The epitaxial pattern 305a and the etched epitaxial sacrificial pattern 303a′ are formed by the anisotropic etching.

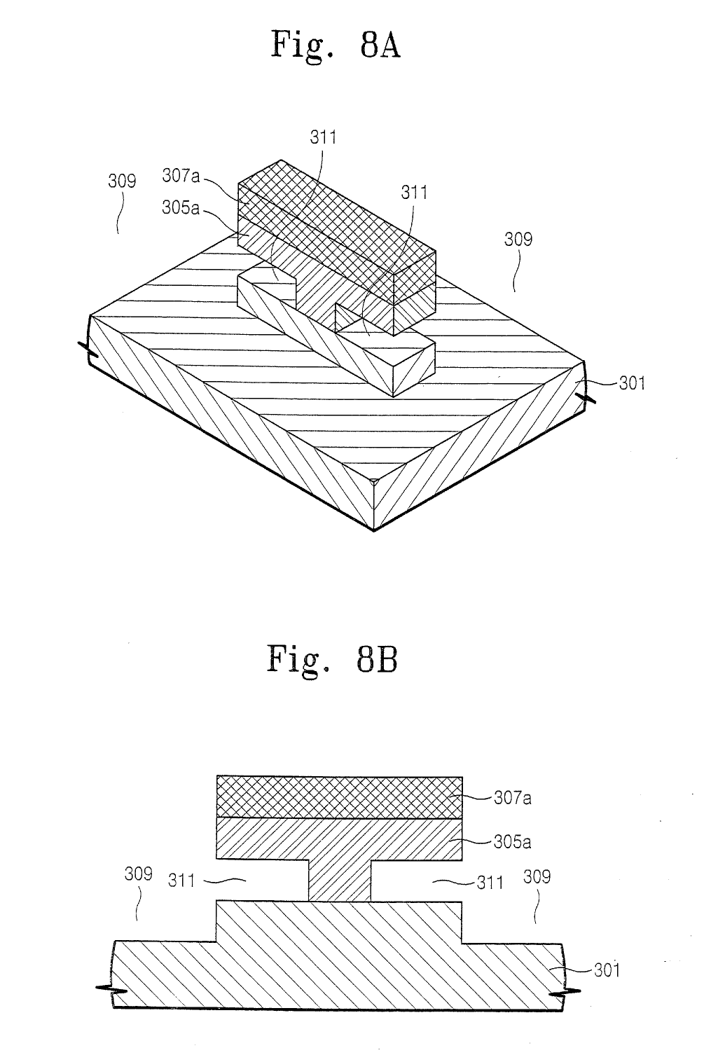

Next, referring to FIG. 8A and FIG. 8B, the epitaxial sacrificial pattern 303a′ exposed by the trench 309, is selectively removed. As a result, an empty space or void region 311 corresponding to the region where the etched epitaxial sacrificial pattern 303a′ is removed is formed. The empty space or void region 311 opens to the trench 309. Consequently, the substrate 301 and the epitaxial pattern 305a are exposed by the trench 309 and the empty space or void region 311.

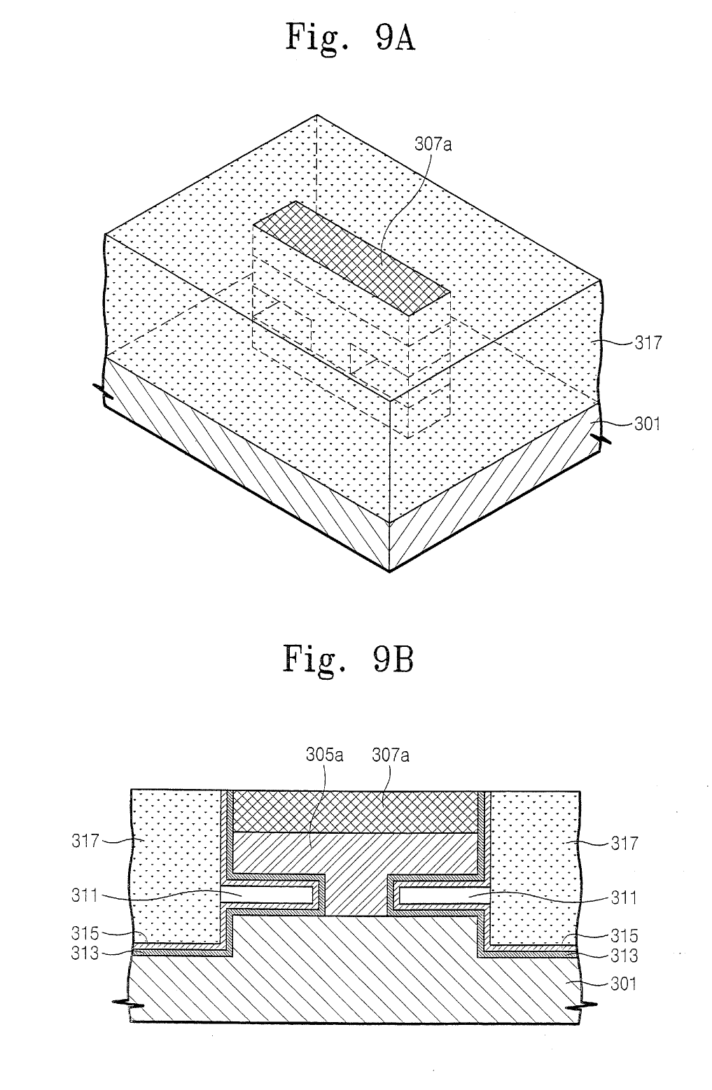

Referring now to FIG. 9A and FIG. 9B, a device isolation region 317 is formed in the trench 309. An insulating material is formed on the mask pattern 307a and in the trench 309 and is then planarized until the mask pattern 307a is exposed to form the device isolation region 317. The planarizing process may be performed using chemical mechanical polishing (CMP) or an etch back process. Before forming the insulating material, a thermal oxidation layer 313 may be formed through a thermal oxidation process and a liner nitride layer 315 may be formed on the thermal oxidation layer 313. The thermal oxidation layer 313 and the liner nitride layer 315 are formed inside the trench as well as the empty space or void region 311.

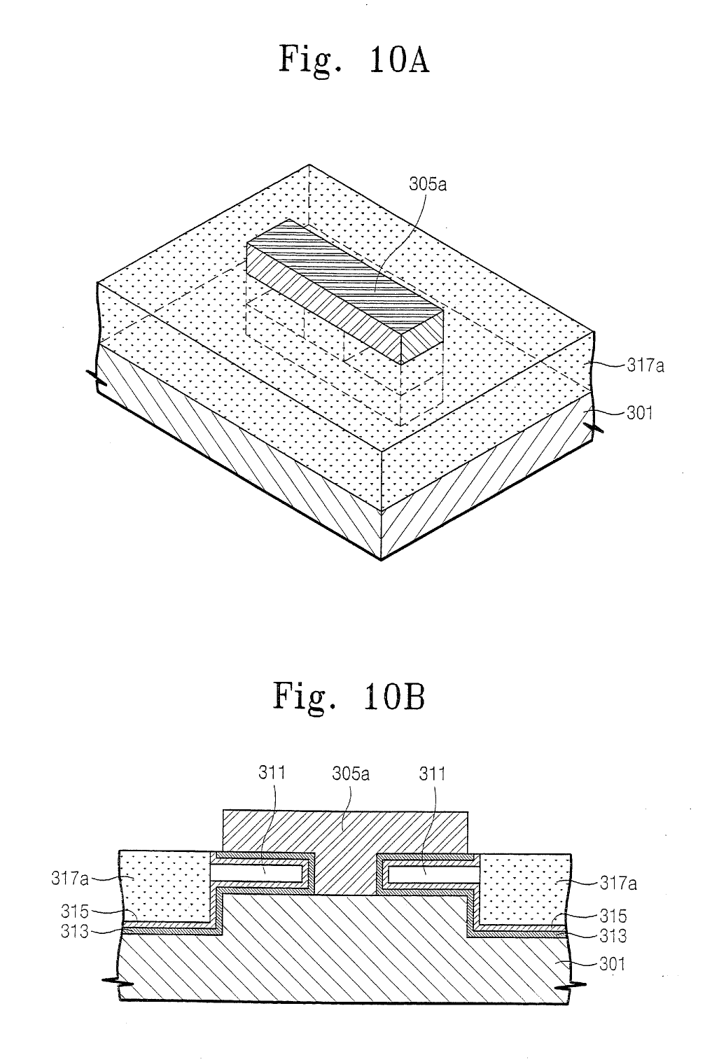

Referring now to FIG. 10A and FIG. 10B, after selectively removing the exposed mask pattern 307a, the device isolation region 317 is etched to form a device isolation region 317a. The top of the device isolation region 317a is lower than the epitaxial pattern 305a. The device isolation region 317 may be etched naturally in a subsequent cleaning process, for example.

As shown in FIG. 1A and FIG. 1B, a gate electrode 319 crossing the epitaxial pattern 305a is formed. The gate electrode 319 crosses over the epitaxial pattern 305a between the empty space or void regions 311. Impurity ions are implanted in the epitaxial pattern 305a and then a thermal treatment is performed to form impurity diffusion regions 321 in the epitaxial pattern 305a outside of the gate electrode 319 over the empty space or void regions 311. When ions are implanted for the impurity diffusion regions 321, a gate can be doped simultaneously. The impurity diffusion regions 321 may be source/drain regions, for example.

The depth of the impurity diffusion regions 321 is determined based on the thickness of the epitaxial pattern 305a. Accordingly, the epitaxial pattern 305a may be formed to suit various device characteristics by controlling the thickness of the epitaxial pattern 305a. In addition, because the empty space or void regions 311 are formed between the epitaxial pattern 305a and the substrate on both sides of the gate electrode 319, the range of conditions for performing an ion implantation and thermal processing for forming the impurity diffusion regions 321 is increased.

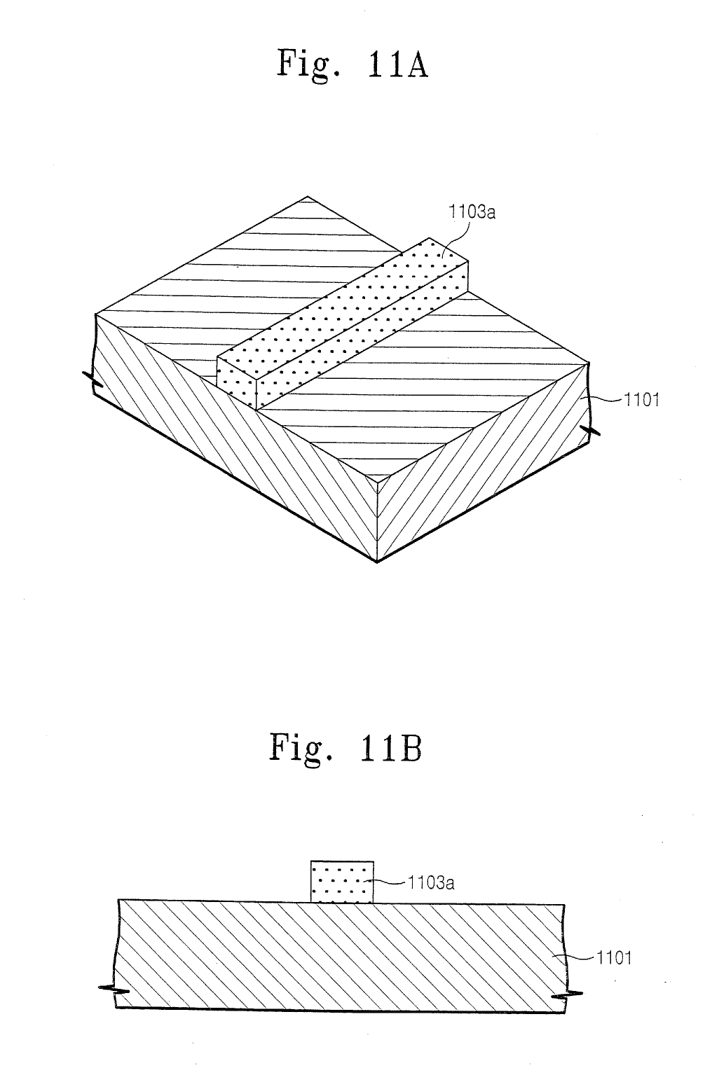

Referring now to FIG. 11A through FIG. 17A and FIG. 11B through FIG. 17B, methods of fabricating integrated circuit devices illustrated, for example, in FIG. 2A and FIG. 2B are described. As shown in FIG. 3A and FIG. 3B, an epitaxial sacrificial layer is formed on a substrate 1101. The epitaxial sacrificial layer is patterned, as shown in FIG. 11A and FIG. 11B, to form an epitaxial sacrificial pattern 1103a, which exhibits a rod-shape. In contrast to the embodiments discussed above, the epitaxial sacrificial pattern 1103a is formed on the region corresponding to the groove 304 of FIG. 4A and FIG. 4B.

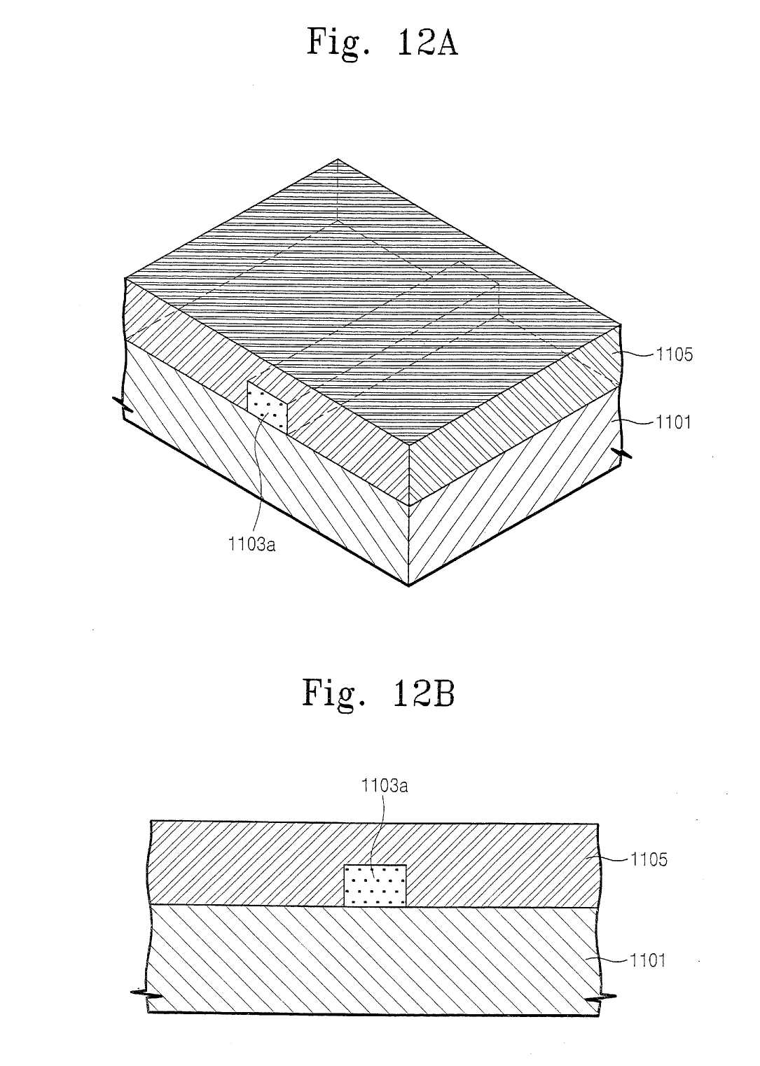

Referring now to FIG. 12A and FIG. 12B, an epitaxial layer 1105, the top of which is planarized, is formed on the epitaxial sacrificial pattern 1103a and the exposed substrate 1101. The epitaxial layer 1105 may be a silicon layer.

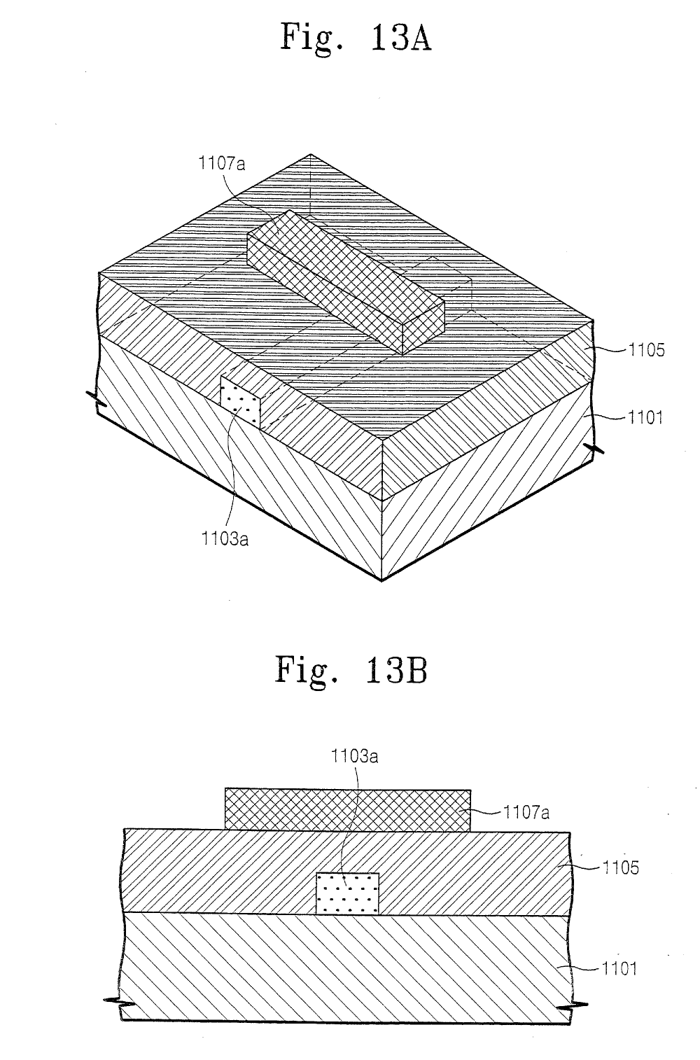

Referring now to FIG. 13A and FIG. 13B, a mask pattern 1107a is formed on the epitaxial pattern 1105. The portion of the epitaxial layer 1105 covered by the mask pattern 1107a serves as an active region. The mask pattern 1107a is formed to cross the epitaxial sacrificial pattern 1103a.

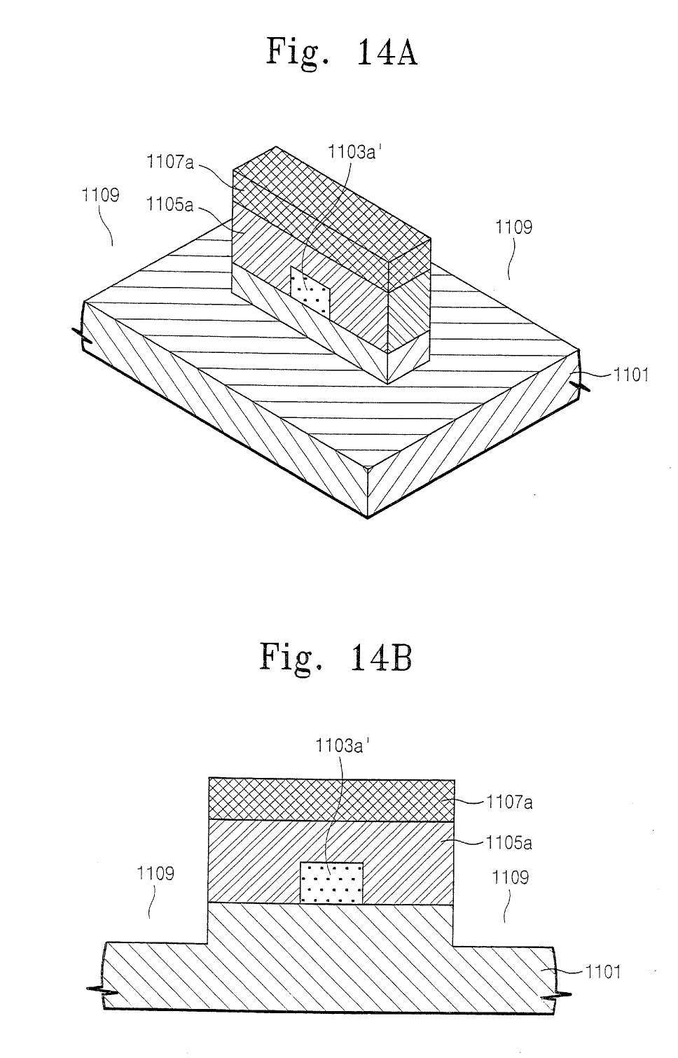

Referring now to FIG. 14A and FIG. 14B, an etching process is performed to remove the epitaxial layer 1105 exposed by the mask pattern 1107a, the epitaxial sacrificial pattern 1103a under the epitaxial layer 1105 exposed by the mask pattern 1107a, and a portion of the substrate 1101. As a result, the epitaxial pattern 1105a and the etched epitaxial sacrificial pattern 1103a′ are formed and a trench 1109 for device isolation is also formed. The trench 1109 exposes the epitaxial pattern 1105a, the etched epitaxial sacrificial pattern 1103a′, and a portion of the substrate 1101.

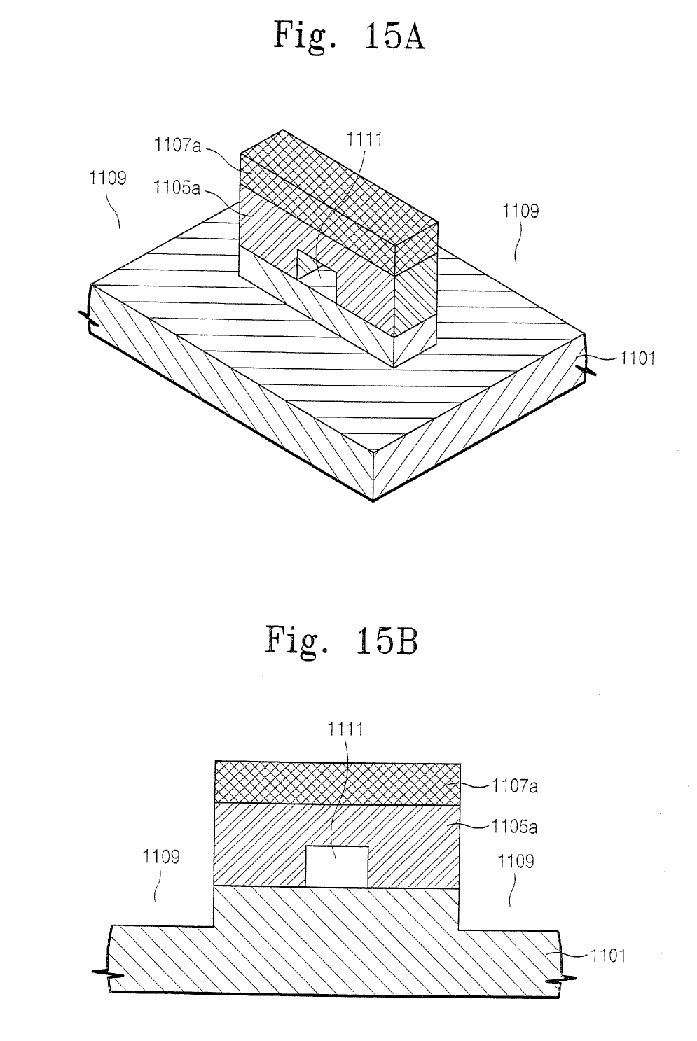

Referring now to FIG. 15A and FIG. 5B, the etched epitaxial sacrificial pattern 1103a′ exposed by the trench 1109 is removed. Accordingly, an empty space or void region 1111 is formed where the etched epitaxial sacrificial pattern 1103a′ is removed.

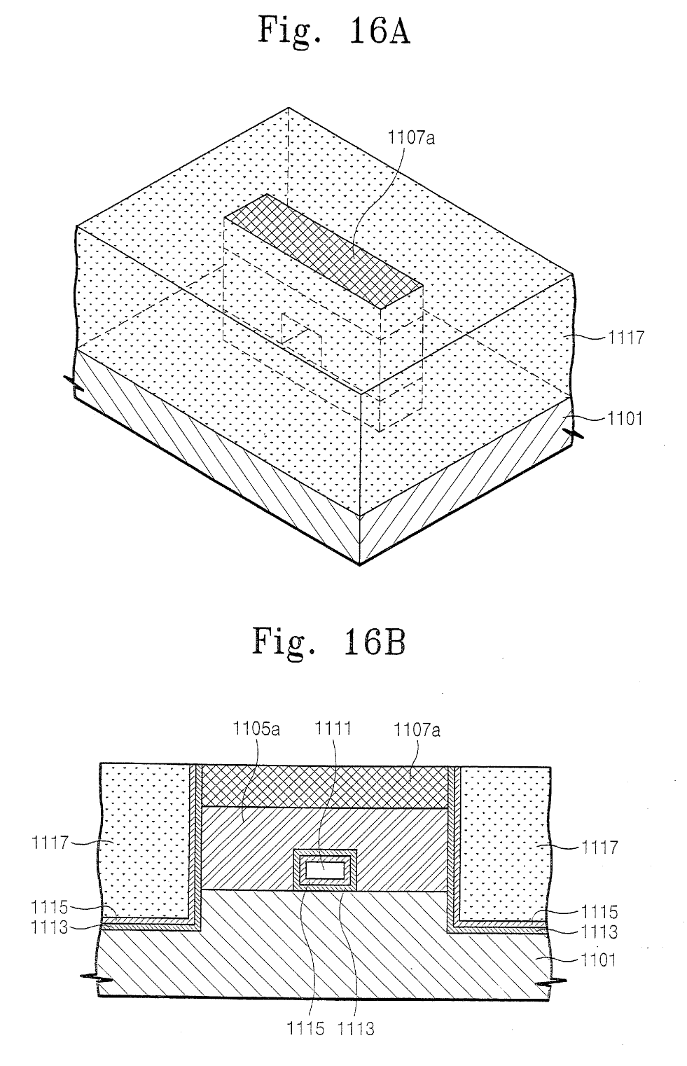

Referring now to FIG. 16A and FIG. 16B, as described above with respect to FIG. 9A and FIG. 9B, a device isolation region 1117 is formed in the trench 1109. An insulating material is formed on the mask pattern 1107a and in the trench 1109 and is then planarized until the mask pattern 1107a is exposed to form the device isolation region 1117. The planarizing process may be performed using chemical mechanical polishing (CMP) or an etch back process. Before forming the insulating material, a thermal oxidation layer 1113 may be formed through a thermal oxidation process and a liner nitride layer 1115 may be formed on the thermal oxidation layer 1113. The thermal oxidation layer 1113 and the liner nitride layer 1115 are formed inside the trench as well as the empty space or void region 1111.

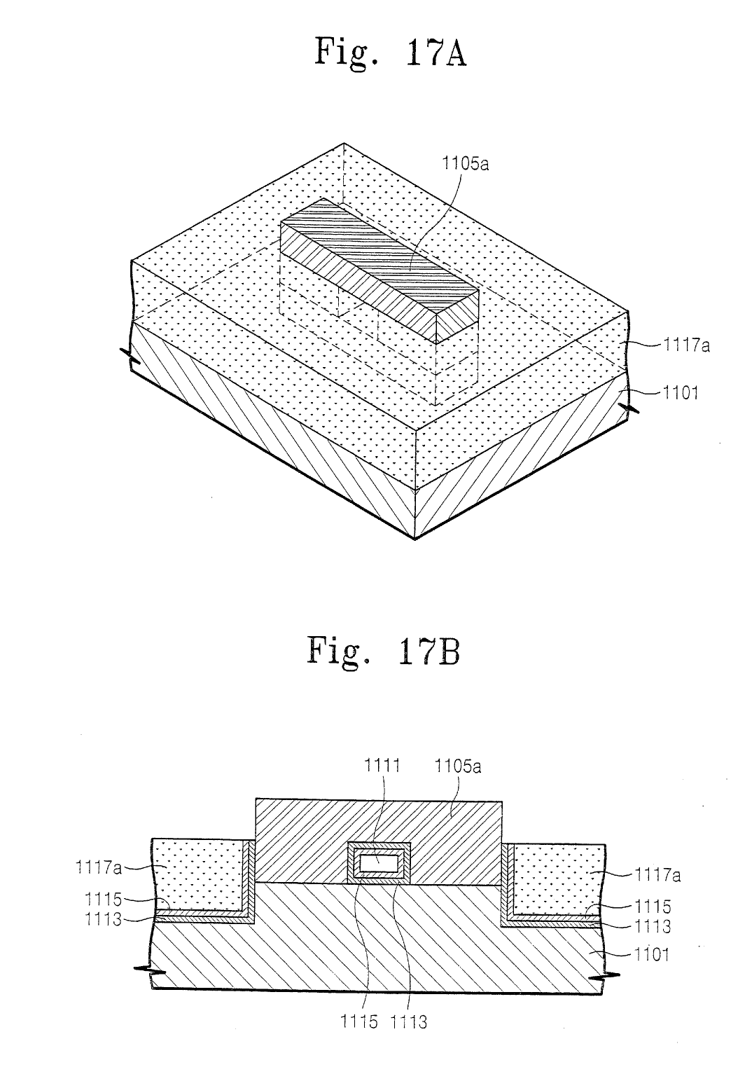

Referring now to FIG. 17A and FIG. 17B, after selectively removing the exposed mask pattern 1107a, the device isolation region 1117 is etched to form a device isolation region 1117a. The top of the device isolation region 1117a is lower than the epitaxial pattern 1105a. The device isolation region 1117 may be etched naturally in a subsequent cleaning process, for example.

As shown in FIG. 2A and FIG. 2B, a gate electrode 1119 crossing the epitaxial pattern 1105a is formed. The gate electrode 1119 crosses over the epitaxial pattern 1105a above the empty space or void region 1111. Impurity ions are implanted in the epitaxial pattern 1105a and then a thermal treatment is performed to form impurity diffusion regions 1121 in the epitaxial pattern 1105a outside of the gate electrode 319. When ions are implanted for the impurity diffusion regions 1121, a gate can be doped simultaneously. The impurity diffusion regions 1121 may be source/drain regions, for example.

Advantageously, according to some embodiments of the present invention, a short channel effect can be reduced because an insulating region (e.g., an empty space or void region) may be formed between the impurity diffusion regions and the substrate and/or between a channel region and the substrate. Furthermore, these embodiments may be implemented without using SOI methodologies, which may provide cost advantages. In addition, floating body effects may be reduced because the epitaxial pattern is in contact with the substrate.

In concluding the detailed description, it should be noted that many variations and modifications can be made to the described embodiments without substantially departing from the principles of the present invention. All such variations and modifications are intended to be included herein within the scope of the present invention, as set forth in the following claims.

That which is claimed:

1. A method of fabricating a semiconductor device comprising:
forming an epitaxial sacrificial pattern on a semiconductor substrate;
forming an epitaxial layer on the epitaxial sacrificial pattern and on the substrate exposed by the epitaxial sacrificial pattern;
etching the epitaxial layer, the epitaxial sacrificial pattern, and a partial thickness of the substrate to form an epitaxial pattern from the epitaxial layer and a trench in the substrate;
removing the etched epitaxial sacrificial pattern exposed by the trench;
forming a device isolation region filling the trench such that a top surface of the device isolation region is lower than a top surface of the epitaxial sacrificial pattern;
forming a gate electrode crossing the epitaxial pattern; and
forming impurity diffusion regions in the epitaxial pattern at both sides of the gate electrode.

2. The method of fabricating the semiconductor device of claim 1, wherein forming the epitaxial pattern and a trench for a device isolation comprises:
forming a mask pattern on the epitaxial layer;
etching the epitaxial layer, the epitaxial sacrificial pattern and a partial thickness of the substrate using the mask pattern as an etching mask; and
wherein forming the device isolation region comprises:
forming an insulating material on the mask pattern to fill the trench;
using a planarizing etch of the insulating material until exposing the mask pattern;
removing the exposed mask pattern; and
etching back the insulating materials such that a top surface of the insulating materials is lower than the epitaxial pattern.

3. The method of fabricating the semiconductor device of claim 2, further comprising the following before forming the insulating material:
forming a thermal oxide layer in the etched epitaxial sacrificial pattern and the trench by performing a thermal oxidation process; and
forming a liner nitride layer on the thermal oxide layer.

4. The method of fabricating the semiconductor device of claim 1, wherein the insulating material fills a region where the etched epitaxial sacrificial pattern is removed.

5. The method of fabricating the semiconductor device of claim 1, wherein the region where the etched epitaxial sacrificial pattern is removed is disposed between the epitaxial pattern at both sides of the gate electrode and the substrate.

6. The method of fabricating the semiconductor device of claim 1, wherein the region where the etched epitaxial sacrificial pattern is removed is disposed between the epitaxial pattern under the gate electrode and the substrate.

7. The method of fabricating the semiconductor device of claim 1, wherein the epitaxial layer comprises a silicon layer.

8. The method of fabricating the semiconductor device of claim 7, wherein the epitaxial sacrificial layer has the same crystalline structure as silicon and lattice constant similar to silicon.

9. The method of fabricating the semiconductor device of claim 8, wherein the epitaxial sacrificial layer comprises Si—Ge, CeO₂, and/or CaF₂.

10. The method of fabricating the semiconductor device of claim 1, wherein the epitaxial sacrificial layer comprises Si—Ge, CeO₂, and/or CaF₂.

11. The method of fabricating the semiconductor device of claim 1, wherein the epitaxial sacrificial layer comprises silicon and the epitaxial layer comprises silicon-germanium.
